(19) United States
(12) Patent Application Publication
(10) Pub. No.: US 2026/0016749 A1
(43) Pub. Date: Jan. 15, 2026

(54) PHOTOSENSITIVE RESIN COMPOSITION, PHOTOSENSITIVE ELEMENT, PRINTED WIRING BOARD, AND METHOD FOR MANUFACTURING PRINTED WIRING BOARD

(71) Applicant: Resonac Corporation, Tokyo (JP)

(72) Inventors: Kaho YAMAGUCHI, Tokyo (JP); Hayato SAWAMOTO, Tokyo (JP); Yasuyuki OYAMA, Tokyo (JP); Naoki YAMASHITA, Tokyo (JP); Arisa YAMAKAWA, Tokyo (JP)

(21) Appl. No.: 18/859,035

(22) PCT Filed: Mar. 14, 2024
(86) PCT No.: PCT/JP2024/010091

§ 371 Date: Oct. 22, 2024

(30) Foreign Application Priority Data
Apr. 6, 2023 (WO) PCT/JP2023/014287

(51) Int. Cl. G03F 7/031; G03F 7/033; G03F 7/115; G03F 7/40; H05K 1/03; H05K 3/06

(52) U.S. Cl. CPC G03F 7/031; G03F 7/033; G03F 7/115; G03F 7/40; H05K 1/0373; H05K 3/064; H05K 2201/0209

(57) ABSTRACT

A photosensitive resin composition, containing: an acid-modified vinyl group-containing resin (A); a photopolymerization initiator (B); a photopolymerizable compound (C); and polymerization inhibitor (D), in which the photopolymerization initiator (B) includes an alkyl phenone-based photopolymerization initiator (B1), an oxime ester-based photopolymerization initiator (B2), and a benzophenone-based photopolymerization initiator (B3).

### TECHNICAL FIELD

The present disclosure relates to a photosensitive resin composition, a photosensitive element, a printed circuit board, and a method for producing a printed circuit board.

### BACKGROUND ART

In the field of producing a printed circuit board, a permanent resist is formed on the printed circuit board. The permanent resist has a function of preventing the corrosion of a conductor layer or retaining an electrical insulating property between the conductor layers when the printed circuit board is used. Recently, in a step of mounting a semiconductor element on the printed circuit board through solder by flip-chip packaging, wire bonding packaging, and the like, the permanent resist has been set to have a function as a solder resist film that prevents the solder from being attached to an unnecessary portion of the conductor layer of the printed circuit board.

In the related art, the permanent resist in the production of the printed circuit board is produced by screen printing using a thermosetting resin composition or photolithography using a photosensitive resin composition. For example, in a flexible wiring board using a packaging method such as flip chip (FC), tape automated bonding (TAB), and chip on film (COF), a thermosetting resin paste is screen-printed except for an IC chip, an electronic part or a liquid crystal display (LCD) panel, and a connecting wiring portion, and thermally cured to form a permanent resist (for example, refer to Patent Literature 1).

In addition, in a semiconductor package substrate such as a ball grid array (BGA) and a chip size package (CSP) mounted on an electronic part, (1) in order to mount a semiconductor element on the semiconductor package substrate through solder by flip-chip packaging, (2) in order to join the semiconductor element and the semiconductor package substrate by wire bonding, or (3) in order to join the semiconductor package substrate onto a motherboard substrate by solder, it is necessary to remove the permanent resist of the joining portion. Therefore, the permanent resist is formed by using photolithography of applying and drying a photosensitive resin composition, and then, selectively curing the photosensitive resin composition by the irradiation of an active ray such as an ultraviolet ray, and developing and removing only an unirradiated portion to form an image. Since the photolithography is suitable for mass production due to excellent workability thereof, in the industry of an electronic material, the photolithography is widely used for the image formation of the photosensitive resin composition (for example, refer to Patent Literatures 2 and 3). In an exposure machine used when applying an active ray, a non-contact type mask projection exposure machine, and a direct lithographic exposure machine in which a mask is not required are widely known. It is considered that the direct lithographic exposure machine in which the mask is not required will be widespread in the future due to high productivity thereof.

### CITATION LIST

### Patent Literature

Patent Literature 1: Japanese Unexamined Patent Publication No. 2003-198105
Patent Literature 2: Japanese Unexamined Patent Publication No. 2011-133851
Patent Literature 3: International Publication WO 2013/022068

### SUMMARY OF INVENTION

### Technical Problem

There are various types of exposure machines, and as a light source of an active ray, not only a light source emitting i-line monochromatic light (a wavelength of 365 nm), but also a light source emitting a mixed line including the i-line and light with a wavelength longer than that of the i-line, such as an h-line (a wavelength of 405 nm), and the like are used. Under such a circumstance, in a case where the same photosensitive resin composition is used for various exposure wavelengths, in accordance with the exposure wavelength, problems such as a decrease in the sensitivity of the photosensitive resin composition, or shape degradation in a via opening portion due to the fact that a via formed in the permanent resist is not opened or a taper angle decreases are likely to occur.

Therefore, an object of the present disclosure is to provide a photosensitive resin composition that has an excellent sensitivity to various exposure wavelengths and is capable of forming a via opening portion with an excellent shape, and a photosensitive element, a printed circuit board, and a method for producing a printed circuit board, using the photosensitive resin composition.

### Solution to Problem

In order to attain the object described above, the present disclosure provides a photosensitive resin composition, a photosensitive element, a printed circuit board, and a method for producing a printed circuit board described below.
[1] A photosensitive resin composition, containing: an acid-modified vinyl group-containing resin (A); a photopolymerization initiator (B); a photopolymerizable compound (C); and a polymerization inhibitor (D), in which the photopolymerization initiator (B) includes an alkyl phenone-based photopolymerization initiator (B1), an oxime ester-based photopolymerization initiator (B2), and a benzophenone-based photopolymerization initiator (B3).
[2] The photosensitive resin composition according to [1] described above, in which a content of the alkyl phenone-based photopolymerization initiator (B1) is 30% by mass or more, on the basis of a total amount of the alkyl phenone-based photopolymerization initiator (B1), the oxime ester-based photopolymerization initiator (B2), and the benzophenone-based photopolymerization initiator (B3).
[3] The photosensitive resin composition according to [1] or [2] described above, in which a content of the oxime ester-based photopolymerization initiator (B2) is 0.5 to 30% by mass, on the basis of the total amount of the alkyl phenone-based photopolymerization initiator (B1), the oxime ester-based photopolymerization initiator (B2), and the benzophenone-based photopolymerization initiator (B3).
[4] The photosensitive resin composition according to any of [1] to [3] described above, in which a content of the benzophenone-based photopolymerization initiator (B3) is 0.2 to 50% by mass, on the basis of the total amount of the alkyl phenone-based photopolymerization initiator (B1), the oxime ester-based photopolymerization initiator (B2), and the benzophenone-based photopolymerization initiator (B3).
[5] The photosensitive resin composition according to any of [1] to [4] described above, further containing a sensitizer (E).
[6] The photosensitive resin composition according to any of [1] to [5] described above, further containing a pigment (F).
[7] The photosensitive resin composition according to any of [1] to [6] described above, further containing an inorganic filler (G).
[8] The photosensitive resin composition according to any of [1] to [7] described above, in which the photopolymerization initiator (B) further includes a thioxanthone compound (B4).
[9] The photosensitive resin composition according to [8] described above, in which a content of the thioxanthone compound (B4) is 0.1 to 50 parts by mass, with respect to 100 parts by mass of the total amount of the alkyl phenone-based photopolymerization initiator (B1), the oxime ester-based photopolymerization initiator (B2), and the benzophenone-based photopolymerization initiator (B3).
[10] A photosensitive element, including: a support film; and a photosensitive layer formed on the support film, in which the photosensitive layer contains the photosensitive resin composition according to any of [1] to [9] described above.
[11] A printed circuit board, including a permanent resist including a cured product of the photosensitive resin composition according to any of [1] to [9] described above.
[12] A method for producing a printed circuit board, including: a step of forming a photosensitive layer on a substrate by using the photosensitive resin composition according to any of [1] to [9] described above; a step of exposing and developing the photosensitive layer to form a resist pattern; and a step of curing the resist pattern to form a permanent resist.
[13] A method for producing a printed circuit board, including: a step of forming a photosensitive layer on a substrate by using the photosensitive element according to [10] described above; a step of exposing and developing the photosensitive layer to form a resist pattern; and a step of curing the resist pattern to form a permanent resist.

### Advantageous Effects of Invention

According to the present disclosure, it is possible to provide the photosensitive resin composition that has an excellent sensitivity to various exposure wavelengths and is capable of forming the via opening portion with an excellent shape, and the photosensitive element, the printed circuit board, and the method for producing a printed circuit board, using the photosensitive resin composition.

### BRIEF DESCRIPTION OF DRAWINGS

FIG. 1 is a cross-sectional view schematically illustrating a photosensitive element according to this embodiment.

FIG. 2 is a cross-sectional view schematically illustrating a via opening portion formed in a permanent resist.

### DESCRIPTION OF EMBODIMENTS

Hereinafter, the present disclosure will be described in detail. In this specification, the term “step” includes not only an independent step but also a step that is not explicitly distinguishable from other steps insofar as a desired function of the step is attained. The term “layer” includes not only a structure in which a layer is formed on the entire surface but also a structure in which a layer is formed on a part of the surface when observed as a plan view. A numerical range represented by using “to” indicates a range including numerical values described before and after “to” as the minimum value and the maximum value, respectively. In numerical ranges described in stages in this specification, the upper limit value or the lower limit value of a numerical range in a certain stage may be replaced with the upper limit value or the lower limit value of a numerical range in the other stage. In the numerical range described in this specification, the upper limit value or the lower limit value of the numerical range may be replaced with values described in Examples.

In a case where there are a plurality of substances corresponding to each component in a composition, the content of each component in the composition indicates the total amount of the plurality of substances in the composition, unless otherwise specified.

In this specification, “(meth)acrylate” indicates at least one of “acrylate” and “methacrylate” corresponding thereto, and the same also applies to other similar expressions such as a (meth)acrylic acid and (meth)acryloyl. In this specification, a “solid content” indicates a non-volatile content excluding a volatile substance (water, a solvent, or the like) in a photosensitive resin composition, and also includes a component in the form of a liquid, syrup, or a wax at a room temperature (approximately 25° C.).

### [Photosensitive Resin Composition]

A photosensitive resin composition according to this embodiment contains an acid-modified vinyl group-containing resin (A), a photopolymerization initiator (B), a photopolymerizable compound (C), and a polymerization inhibitor (D), and the photopolymerization initiator (B) includes an alkyl phenone-based photopolymerization initiator (B1), an oxime ester-based photopolymerization initiator (B2), and a benzophenone-based photopolymerization initiator (B3). By having the configuration described above, the photosensitive resin composition according to this embodiment has an excellent sensitivity to various exposure wavelengths and is capable of forming a via opening portion with an excellent shape. The photosensitive resin composition according to this embodiment can be used to form a permanent resist. The photosensitive resin composition according to this embodiment is a negative photosensitive resin composition, and a cured film of the photosensitive resin composition can be used as the permanent resist. Hereinafter, each component used for the photosensitive resin composition of this embodiment will be described in detail.

### (Component (A): Acid-Modified Vinyl Group-Containing Resin)

The photosensitive resin composition according to this embodiment contains the acid-modified vinyl group-containing resin as a component (A). The acid-modified vinyl group-containing resin is not particularly limited insofar as the acid-modified vinyl group-containing resin has a vinyl group that is a photopolymerizable ethylenically unsaturated bond and an alkali-soluble acid group. Examples of the acid group in the acid-modified vinyl group-containing resin include a carboxy group, a sulfo group, and a phenolic hydroxyl group. Among them, from the viewpoint of a resolution, the carboxy group is preferable.

Examples of the acid-modified vinyl group-containing resin include an acid-modified vinyl group-containing epoxy resin and an acid-modified vinyl group-containing phenol resin.

Examples of the acid-modified vinyl group-containing epoxy resin include acid-modified epoxy (meth)acrylate. The acid-modified epoxy (meth)acrylate is a resin in which epoxy (meth)acrylate that is a reactant between an epoxy resin and an organic acid having a vinyl group is subjected to acid modification. As the acid-modified epoxy (meth)acrylate, for example, an addition reactant in which a saturated or unsaturated polybasic anhydride (c) is added to an esterified product obtained by a reaction between an epoxy resin (a) and a vinyl group-containing monocarboxylic acid (b) can be used.

Examples of the epoxy resin (a) include a bisphenol novolac-type epoxy resin, a novolac-type epoxy resin, a bisphenol A-type epoxy resin, a bisphenol F-type epoxy resin, a triphenol methane-type epoxy resin, a biphenyl-type epoxy resin, a naphthalene-type epoxy resin, and a dicyclopentadiene-type epoxy resin. Among them, it is preferable that the epoxy resin (a) includes at least one type selected from the group consisting of a dicyclopentadiene-type epoxy resin and a bisphenol F novolac-type epoxy resin, from the viewpoint of the resolution. In addition, it is preferable that the epoxy resin (a) does not have a fluorene skeleton, from the viewpoint of a developing property.

Examples of the vinyl group-containing monocarboxylic acid (b) include an acrylic acid derivative such as an acrylic acid, a dimer of an acrylic acid, a methacrylic acid, β-furfuryl acrylate, β-styryl acrylate, a cinnamic acid, a crotonic acid, and an α-cyanocinnamic acid, a half ester compound that is a reaction product between hydroxyl group-containing (meth)acrylate and a dibasic acid anhydride, and a half ester compound that is a reaction product between vinyl group-containing monoglycidyl ether or vinyl group-containing monoglycidyl ester and a dibasic acid anhydride.

Examples of the hydroxyl group-containing (meth)acrylate, the vinyl group-containing monoglycidyl ether, and the vinyl group-containing monoglycidyl ester include hydroxyethyl acrylate, hydroxyethyl methacrylate, hydroxypropyl acrylate, hydroxypropyl methacrylate, hydroxybutyl acrylate, hydroxybutyl methacrylate, polyethylene glycol monoacrylate, polyethylene glycol monomethacrylate, trimethylol propane diacrylate, trimethylol propane dimethacrylate, pentaerythritol triacrylate, pentaerythritol trimethacrylate, dipentaerythritol pentaacrylate, pentaerythritol pentamethacrylate, glycidyl acrylate, and glycidyl methacrylate.

Examples of the dibasic acid anhydride include a succinic anhydride, a maleic anhydride, a tetrahydrophthalic anhydride, a phthalic anhydride, a methyl tetrahydrophthalic anhydride, an ethyl tetrahydrophthalic anhydride, a hexahydrophthalic anhydride, a methyl hexahydrophthalic anhydride, an ethyl hexahydrophthalic anhydride, and an itaconic anhydride.

Examples of the saturated or unsaturated polybasic anhydride (c) include a succinic anhydride, a maleic anhydride, a tetrahydrophthalic anhydride, a phthalic anhydride, a methyl tetrahydrophthalic anhydride, an ethyl tetrahydrophthalic anhydride, a hexahydrophthalic anhydride, a methyl hexahydrophthalic anhydride, an ethyl hexahydrophthalic anhydride, and an itaconic anhydride. Among them, from the viewpoint of obtaining the photosensitive resin composition capable of forming a pattern excellent in the resolution, the tetrahydrophthalic anhydride may be used as the polybasic anhydride.

The acid value of the component (A) is not particularly limited. The acid value of the component (A), from the viewpoint of improving the solubility of an unexposed portion with respect to an alkaline aqueous solution, may be 30 mgKOH/g or more, 40 mgKOH/g or more, or 50 mgKOH/g or more. The acid value of the component (A), from the viewpoint of improving the electrical property of the cured film, may be 150 mgKOH/g or less, 120 mgKOH/g or less, or 100 mgKOH/g or less.

The weight average molecular weight (Mw) of the component (A) is not particularly limited. Mw of the component (A), from the viewpoint of improving the adhesiveness of the cured film, may be 3000 or more, 4000 or more, or 5000 or more. Mw of the component (A), from the viewpoint of improving the resolution of a photosensitive layer, may be 30000 or less, 25000 or less, or 18000 or less. Mw can be measured by a gel permeation chromatography (GPC) method.

The content of the component (A) in the photosensitive resin composition, from the viewpoint of improving the heat resistance, the electrical property, and the chemical resistance of the cured film, may be 20 to 70% by mass, 25 to 60% by mass, or 30 to 50% by mass, on the basis of the total solid content of the photosensitive resin composition.

### (Component (B): Photopolymerization Initiator)

The photosensitive resin composition according to this embodiment contains the alkyl phenone-based photopolymerization initiator (B1) (hereinafter, also referred to as a “component (B1)”), the oxime ester-based photopolymerization initiator (B2) (hereinafter, also referred to as a “component (B2)”), and the benzophenone-based photopolymerization initiator (B3) (hereinafter, also referred to as a “component (B3)”), as a component (B). By using the component (B1), the component (B2), and the component (B3) together, the photosensitive resin composition according to this embodiment is capable of suppressing a change in a light absorbance due to an exposure wavelength, has an excellent sensitivity to various exposure wavelengths, and is capable of forming the via opening portion with an excellent shape.

Here, since the component (B1) has an absorption spectrum of 300 nm or more, an effect of enabling curing even in an exposure condition of a long wavelength range is attained. From the viewpoint of further improving such an effect, it is preferable that the component (B1) has an absorption maximum at 260 nm or more in a wavelength range of 220 nm or more. In addition, the component (B2) is capable of generating radical species with a small size. Since the radical species are easily moved in the resin, an effect of enabling the photosensitive resin composition to be efficiently cured and have a high sensitivity is attained. In addition, since the component (B3) causes intersystem crossing from a singlet excited state to a triplet excited state when irradiated with ultraviolet light, the component functions as a sensitizer, and the effect of enabling the photosensitive resin composition to be efficiently cured and have a high sensitivity is attained.

Examples of the component (B1) include 2-benzyl-2-dimethyl amino-1-(4-morpholinophenyl)-butanone-1, 2-methyl-1-[4-(methylthio)phenyl]-2-morpholino-1-propanone, 2-hydroxy-1-[4-(2-hydroxyethoxy)phenyl]-2-methyl-1-propanone, 2,2-dimethoxy-2-phenyl acetophenone, and 2,2-diethoxy-2-phenyl acetophenone. Note that the component (B1) is a compound that does not correspond to either the component (B2) or the component (B3), that is, a compound that does not have an oxime ester structure and does not have a benzophenone skeleton. Only one type of the component may be used alone, or two or more types thereof may be used in combination.

Examples of the component (B2) include 1-[9-ethyl-6-(2-methyl benzoyl)-9H-carbazol-3-yl]ethanone 1-(O-acetyl oxime), 1-[4-(phenyl thio)phenyl] octane-1,2-dione-2-(O-benzoyl oxime), and 1-phenyl-1,2-propane dione-2-[O-(ethoxycarbonyl) oxime]. Only one type of the component may be used alone, or two or more types thereof may be used in combination.

Examples of the component (B3) include benzophenone, 4,4′-bis(dimethyl amino)benzophenone (Michler's ketone), 4,4′-bis(diethylamino)benzophenone, 4-methoxy-4′-dimethyl aminobenzophenone, 4,4′-dichlorobenzophenone, and 4-benzoyl-4′-methyl diphenyl sulfide. Note that the component (B3) is a compound that does not correspond to the component (B2), that is, a compound that does not have an oxime ester structure. Only one type of the component may be used alone, or two or more types thereof may be used in combination.

The component (B) may contain other photopolymerization initiators in addition to the component (B1), the component (B2), and the component (B3). Examples of the other photopolymerization initiator include a xanthone compound, a thioxanthone compound, an anthraquinone compound, a ketal compound, an imidazole compound, an acridine compound, an acyl phosphine oxide compound, and a tertiary amine compound. Among them, it is preferable that the component (B) contains a thioxanthone compound (B4) (hereinafter, also referred to as a “component (B4)”).

Among the photopolymerization initiators, examples of the thioxanthone compound (B4) include thioxanthone, 2-isopropyl thioxanthone, 2-dodecyl thioxanthone, 2-cyclohexyl thioxanthone, 2,4-diethyl thioxanthone, 2,4-dimethyl thioxanthone, 1-phenoxythioxanthone, 1-methoxycarbonyl thioxanthone, 2-ethoxycarbonyl thioxanthone, 3-(2-methoxyethoxycarbonyl)-thioxanthone, 4-butoxycarbonyl thioxanthone, 3-butoxycarbonyl-7-methyl thioxanthone, 3,4-di-[2-(2-methoxyethoxy)-ethoxycarbonyl]-thioxanthone, 2-chlorothioxanthone, 1-ethoxycarbonyl-3-ethoxythioxanthone, 1-ethoxycarbonyl-3-chlorothioxanthone, 1-chloro-4-n-propoxythioxanthone, 2-methyl-6-dimethoxymethyl-thioxanthone, 2-methyl-6-(1,1-dimethoxybenzyl)-thioxanthone, 6-ethoxycarbonyl-2-methoxy-thioxanthone, 6-ethoxycarbonyl-2-methyl thioxanthone, 1-ethoxycarbonyl-3-(1-methyl-1-morpholinoethyl)-thioxanthone, 2-morpholinomethyl thioxanthone, 2-methyl-6-morpholinomethyl thioxanthone, and thioxanthone-2-carboxylic acid polyethylene glycol ester.

The thioxanthone compound that is the component (B4) has a triplet energy sensitization action, and is combined with a suitable photopolymerization initiator to enable light on a long wavelength side to be used for radical generation. Therefore, by using the component (B4) in combination with the component (B1), the component (B2), and the component (B3) in the photosensitive resin composition, it is possible to further improve the sensitivity to various exposure wavelengths, and make the shape of the via opening portion more excellent.

The content of the component (B1) in the component (B) may be 30% by mass or more, 35 to 99% by mass, or 40 to 98% by mass, on the basis of the total amount of the component (B1), the component (B2), and the component (B3). In a case where the content of the component (B1) is in the range described above, there is a tendency that the sensitivity can be further improved.

The content of the component (B2) in the component (B) may be 0.5 to 30% by mass, 1.0 to 25% by mass, or 1.5 to 20% by mass, on the basis of the total amount of the component (B1), the component (B2), and the component (B3). In a case where the content of the component (B2) is in the range described above, there is a tendency that it is possible to further improve the sensitivity to various exposure wavelengths, and make the shape of the via opening portion more excellent.

The content of the component (B3) in the component (B) may be 0.2 to 50% by mass, 0.4 to 45% by mass, or 0.6 to 40% by mass, on the basis of the total amount of the component (B1), the component (B2), and the component (B3). In a case where the content of the component (B3) is in the range described above, there is a tendency that it is possible to further improve the sensitivity to various exposure wavelengths, and make the shape of the via opening portion more excellent.

The content of the component (B4) in the component (B) may be 0.1 parts by mass or more, 0.5 parts by mass or more, 1 part by mass or more, 3 parts by mass or more, or 5 parts by mass or more, and may be 50 parts by mass or less, 40 parts by mass or less, 30 parts by mass or less, 20 parts by mass or less, or 10 parts by mass or less, with respect to 100 parts by mass of the total amount of the component (B1), the component (B2), and the component (B3). In a case where the content of the component (B4) is 0.1 parts by mass or more, there is a tendency that it is possible to further improve the sensitivity to various exposure wavelengths, and make the shape of the via opening portion more excellent. In a case where the content of the component (B4) is 50 parts by mass or less, there is a tendency that it is possible to further improve the sensitivity to various exposure wavelengths. From such viewpoints, the content of the component (B4) in the component (B) may be 0.1 to 50 parts by mass, 0.5 to 40 parts by mass, 1 to 30 parts by mass, 3 to 20 parts by mass, or 5 to 10 parts by mass, with respect to 100 parts by mass of the total amount of the component (B1), the component (B2), and the component (B3).

The content of the component (B2) in the component (B) may be 0.5 to 60 parts by mass, 1.0 to 55 parts by mass, or 1.5 to 50 parts by mass, with respect to 100 parts by mass of the component (B1). In a case where the content of the component (B2) is 0.5 parts by mass or more, there is a tendency that it is possible to further improve the sensitivity, and in a case where the content is 60 parts by mass or less, there is a tendency that a balance between the sensitivity and the shape of the via opening portion is improved.

The content of the component (B3) in the component (B) may be 0.2 to 110 parts by mass, 0.4 to 105 parts by mass, or 0.6 to 100 parts by mass, with respect to 100 parts by mass of the component (B1). In a case where the content of the component (B3) is 0.2 parts by mass or more, there is a tendency that it is possible to further improve the sensitivity, and in a case where the content is 110 parts by mass or less, there is a tendency that the balance between the sensitivity and the shape of the via opening portion is improved.

The total content of the component (B1), the component (B2), and the component (B3) in the component (B), from the viewpoint of the sensitivity, may be 70% by mass or more, 80% by mass or more, or 90% by mass or more, and may be 100% by mass, less than 100% by mass, 99.5% by mass or less, or 99% by mass or less, on the basis of the total amount of the component (B).

The total content of the component (B1), the component (B2), the component (B3), and the component (B4) in the component (B), from the viewpoint of the sensitivity, may be 70% by mass or more, 80% by mass or more, or 90% by mass or more, and may be 100% by mass, on the basis of the total amount of the component (B).

The content of the component (B) in the photosensitive resin composition is not particularly limited, and may be 0.2 to 15% by mass, 0.5 to 10% by mass, or 1 to 5% by mass, on the basis of the total solid content of the photosensitive resin composition.

### (Component (C): Photopolymerizable Compound)

The photosensitive resin composition according to this embodiment, from the viewpoint of increasing chemical resistance after exposure and increasing a difference in developer resistance between an exposed portion and an unexposed portion, contains the photopolymerizable compound as a component (C). The component (C) is not particularly limited insofar as the component is a photopolymerizable compound that has an ethylenically unsaturated group but does not have an acid group.

Examples of the component (C) include a photopolymerizable compound having one ethylenically unsaturated group, a photopolymerizable compound having two ethylenically unsaturated groups, and a photopolymerizable compound having three or more ethylenically unsaturated groups.

Examples of the photopolymerizable compound having one ethylenically unsaturated group include a (meth)acrylic acid and (meth)acrylic acid alkyl ester. Examples of the (meth)acrylic acid alkyl ester include (meth)acrylic acid methyl ester, (meth)acrylic acid ethyl ester, (meth)acrylic acid butyl ester, (meth)acrylic acid 2-ethyl hexyl ester, and (meth)acrylic acid hydroxyethyl ester.

Examples of the photopolymerizable compound having two ethylenically unsaturated groups include polyethylene glycol di(meth)acrylate, trimethylol propane di(meth)acrylate, polypropylene glycol di(meth)acrylate, 2,2-bis(4-(meth)acryloxypolyethoxypolypropoxyphenyl) propane, and bisphenol A diglycidyl ether di(meth)acrylate.

Examples of the photopolymerizable compound having three or more ethylenically unsaturated groups include a (meth)acrylate compound having a skeleton derived from trimethylol propane, such as trimethylol propane tri(meth)acrylate; a (meth)acrylate compound having a skeleton derived from tetramethylol methane, such as tetramethylol methane tri(meth)acrylate and tetramethylol methane tetra(meth)acrylate; a (meth)acrylate compound having a skeleton derived from pentaerythritol, such as pentaerythritol tri(meth)acrylate and pentaerythritol tetra(meth)acrylate; a (meth)acrylate compound having a skeleton derived from dipentaerythritol, such as dipentaerythritol penta(meth)acrylate and dipentaerythritol hexa(meth)acrylate; a (meth)acrylate compound having a skeleton derived from ditrimethylol propane, such as ditrimethylol propane tetra(meth)acrylate; and a (meth)acrylate compound having a skeleton derived from diglycerine.

Among them, from the viewpoint of increasing the chemical resistance after exposure and increasing the difference in the developer resistance between the exposed portion and the unexposed portion, the (meth)acrylate compound having a skeleton derived from dipentaerythritol is preferable, and the dipentaerythritol penta(meth)acrylate and the dipentaerythritol hexa(meth)acrylate are more preferable.

In a case where the photosensitive resin composition of this embodiment contains the component (C), the content thereof may be 1 to 20% by mass, 2 to 15% by mass, or 4 to 12% by mass, on the basis of the total solid content of the photosensitive resin composition.

### (Component (D): Polymerization Inhibitor)

The photosensitive resin composition of this embodiment contains the polymerization inhibitor as a component (D). By containing the component (D), the photosensitive resin composition according to this embodiment enables curing to the lower portion of the via by suppressing the curing of the upper portion of the via when the via is formed, thereby forming the via opening portion with an excellent shape without having undercut.

Examples of the component (D) include 4-tert-butyl catechol, 4-hydroxy-2,2,6,6-tetramethyl piperidine-N-oxyl, 4,4′-butylidene-bis(6-tert-butyl-m-cresol), hydroquinone, methyl hydroquinone, and hydroquinone monomethyl ether. Only one type of the component may be used alone, or two or more types thereof may be used in combination.

The content of the component (D), from the viewpoint of making the sensitivity, the resolution, and the shape of the via opening portion more excellent, may be 0.01 parts by mass or more, 0.02 parts by mass or more, 0.05 parts by mass or more, or 0.10 parts by mass or more, and from the viewpoint of the sensitivity and the adhesiveness, may be 0.50 parts by mass or less, 0.40 parts by mass or less, or 0.30 parts by mass or less, with respect to 100 parts by mass of the total amount of the component (A) and the component (B).

### (Component (E): Sensitizer)

The photosensitive resin composition of this embodiment may further contain a sensitizer as a component (E). By the photosensitive resin composition containing the component (E), it is possible to effectively utilize the absorption wavelength of an active ray used for exposure.

Examples of the component (E) include a pyrazoline compound, an anthracene compound, a coumarin compound, an oxazole compound, a benzoxazole compound, a thiazole compound, a benzothiazole compound, a triazole compound, a stilbene compound, a triazine compound, a thiophene compound, a naphthal imide compound, a triaryl amine compound, and an aminoacridine compound.

Examples of the pyrazoline compound include 1-phenyl-3-(4-methoxystyryl)-5-(4-methoxyphenyl) pyrazoline, 1-phenyl-3-(4-tert-butyl styryl)-5-(4-tert-butyl phenyl) pyrazoline, and 1-phenyl-3-biphenyl-5-(4-tert-butyl phenyl) pyrazoline.

Examples of the anthracene compound include 9,10-dimethoxyanthracene, 9,10-diethoxyanthracene, 9,10-dipropoxyanthracene, 9,10-dibutoxyanthracene, and 9,10-dipentoxyanthracene.

Examples of the coumarin compound include 3-benzoyl-7-diethyl aminocoumarin, 7-diethyl amino-4-methyl coumarin, 3,3′-carbonyl bis(7-diethyl aminocoumarin), and 2,3,6,7-tetrahydro-9-methyl-1H,5H,11H-[1]benzopyrano [6,7,8-ij]quinolizin-11-one.

The content of the component (E), from the viewpoint of further improving the sensitivity, the adhesiveness, and the resolution, may be 0.01 to 1.5 parts by mass, 0.02 to 1.2 parts by mass, or 0.03 to 1.0 parts by mass, with respect to 100 parts by mass of the total amount of the component (A) and the component (B).

### (Component (F): Pigment)

The photosensitive resin composition of this embodiment, from the viewpoint of improving the distinguishability or the appearance of a production facility, may further contain a pigment as a component (F). As the component (F), a colorant that produces a desired color when hiding wiring can be used. Examples of the component (F) include phthalocyanine blue, phthalocyanine green, iodine green, diazo yellow, crystal violet, titanium oxide, carbon black, and naphthalene black.

The content of the component (F), from the viewpoint of further hiding the wiring, may be 0.05 to 10% by mass, 0.1 to 8% by mass, or 0.2 to 5% by mass, on the basis of the total solid content in the photosensitive resin composition.

### (Component (G): Inorganic Filler)

The photosensitive resin composition according to this embodiment may further contain an inorganic filler as a component (G). By containing the component (G), it is possible to improve the bonding adhesive strength, the reliability, and the like of the permanent resist. Only one type of the component (G) may be used alone, or two or more types thereof may be used in combination.

Examples of the inorganic filler include silica, alumina, titania, tantalum oxide, zirconia, silicon nitride, barium titanate, barium carbonate, magnesium carbonate, aluminum hydroxide, magnesium hydroxide, lead titanate, lead zirconate titanate, lead lanthanum zirconate titanate, gallium oxide, spinel, mullite, cordierite, talc, aluminum titanate, yttria-containing zirconia, barium silicate, boron nitride, calcium carbonate, barium sulfate, calcium sulfate, zinc oxide, magnesium titanate, hydrotalcite, mica, calcined kaolin, and carbon.

The component (G), from the viewpoint of improving the heat resistance of the permanent resist, may include silica, and from the viewpoint of improving the heat resistance and the bonding adhesive strength of the permanent resist, may include barium sulfate. From the viewpoint of improving the dispersibility of the inorganic filler, an inorganic filler of which the surface is treated in advance with an alumina or an organic silane compound may be used.

The average particle size of the inorganic filler may be 0.01 μm or more, 0.1 μm or more, 0.2 μm or more, or 0.3 μm or more, and may be 5.0 μm or less, 3.0 μm or less, 2.0 μm or less, or 1.5 μm or less.

The content of the component (G) may be 5 to 70% by mass, 6 to 60% by mass, 10 to 50% by mass, 20 to 50% by mass, or 30 to 50% by mass, on the basis of the total solid content of the photosensitive resin composition. In a case where the content of the component (G) is in the range described above, a low thermal expansion coefficient, the heat resistance, a film strength, and the like can be further improved. In addition, there is a tendency that as the content of the component (G) increases (that is, the content of the component (G) is the lower limit value or more), the taper angle of the via is likely to increase, and the via opening portion with a more excellent shape can be formed.

### (Component (H): Thermosetting Resin)

The photosensitive resin composition according to this embodiment may further contain a thermosetting resin as a component (H). By using the component (H), it is possible to improve the heat resistance, the bonding adhesiveness, the chemical resistance, and the like of the cured film (the permanent resist) formed from the photosensitive resin composition. Only one type of the component (H) may be used alone, or two or more types thereof may be used in combination.

Examples of the component (H) include an epoxy resin, a phenol resin, an unsaturated imide resin, a cyanate resin, an isocyanate resin, a benzoxazine resin, an oxetane resin, an amino resin, an unsaturated polyester resin, an allyl resin, a dicyclopentadiene resin, a silicone resin, a triazine resin, and a melamine resin.

Examples of the epoxy resin include a bisphenol A-type epoxy resin, a bisphenol F-type epoxy resin, a hydrogenated bisphenol A-type epoxy resin, a brominated bisphenol A-type epoxy resin, a bisphenol S-type epoxy resin, a novolac-type epoxy resin, a biphenyl-type epoxy resin, a naphthalene-type epoxy resin, a dicyclopentadiene-type epoxy resin, a hydantoin-type epoxy resin, triglycidyl isocyanurate, and a bixylenol-type epoxy resin.

The content of the component (H) may be 2 to 30% by mass, 5 to 25% by mass, or 8 to 20% by mass, on the basis of the total solid content of the photosensitive resin composition. In a case where the content of the component (H) is in the range described above, it is possible to further improve the heat resistance of the cured film to be formed while maintaining an excellent developing property.

### (Component (I): Elastomer)

The photosensitive resin composition according to this embodiment may further contain an elastomer as a component (I). By containing the component (I), it is possible to suppress a decrease in flexibility and a bonding adhesive strength caused by strain (an internal stress) in the resin due to the curing shrinkage of the component (A).

Examples of the component (I) include a styrene-based elastomer, an olefin-based elastomer, a urethane-based elastomer, a polyester-based elastomer, a polyamide-based elastomer, an acrylic elastomer, and a silicone-based elastomer. Such elastomers are composed of a hard segment component contributing to the heat resistance and the strength, and a soft segment component contributing to flexibility and toughness.

Examples of the styrene-based elastomer include a styrene-butadiene-styrene block copolymer, a styrene-isoprene-styrene block copolymer, a styrene-ethylene-butylene-styrene block copolymer, and a styrene-ethylene-propylene-styrene block copolymer. As the component configuring the styrene-based elastomer, a styrene derivative such as α-methyl styrene, 3-methyl styrene, 4-propyl styrene, and 4-cyclohexyl styrene can be used, in addition to styrene.

Examples of the olefin-based elastomer include an ethylene-propylene copolymer, an ethylene-α-olefin copolymer, an ethylene-α-olefin-non-conjugated diene copolymer, a propylene-α-olefin copolymer, a butene-α-olefin copolymer, an ethylene-propylene-diene copolymer, a copolymer of non-conjugated diene and α-olefin, such as dicyclopentadiene, 1,4-hexadiene, cyclooctadiene, methylene norbornene, ethylidene norbornene, butadiene, and isoprene, and a carboxylic acid-modified butadiene-acrylonitrile copolymer.

As the urethane-based elastomer, a compound composed of a hard segment consisting of low-molecular-weight (short-chain) diol and diisocyanate, and a soft segment consisting of high-molecular-weight (long-chain) diol and diisocyanate can be used.

Examples of the short-chain diol include ethylene glycol, propylene glycol, 1,4-butane diol, and bisphenol A. It is preferable that the number average molecular weight of the short-chain diol is 48 to 500.

Examples of the long-chain diol include polypropylene glycol, polytetramethylene oxide, poly(1,4-butylene adipate), poly(ethylene-1,4-butylene adipate), polycaprolactone, poly(1,6-hexylene carbonate), and poly(1,6-hexylene-neopentylene adipate). It is preferable that the number average molecular weight of the long-chain diol is 500 to 10000.

As the polyester-based elastomer, a compound in which a dicarboxylic acid or a derivative thereof, and a diol compound or a derivative thereof are polycondensed can be used.

Examples of the dicarboxylic acid include an aromatic dicarboxylic acid such as a terephthalic acid, an isophthalic acid, and a naphthalene dicarboxylic acid; an aliphatic dicarboxylic acid having 2 to 20 carbon atoms, such as an adipic acid, a sebacic acid, and a dodecane dicarboxylic acid; and an alicyclic dicarboxylic acid such as a cyclohexane dicarboxylic acid. Only one type of the dicarboxylic acid can be used alone, or two or more types thereof can be used in combination.

Examples of the diol compound include aliphatic diol such as ethylene glycol, 1,3-propane diol, 1,4-butane diol, 1,6-hexane diol, and 1,10-decane diol; alicyclic diol such as 1,4-cyclohexane diol; and aromatic diol such as bisphenol A, bis-(4-hydroxyphenyl) methane, bis-(4-hydroxy-3-methyl phenyl) propane, and resorcine.

As the polyester-based elastomer, a multiblock copolymer in which aromatic polyester (for example, polybutylene terephthalate) is used for a hard segment component, and aliphatic polyester (for example, polytetramethylene glycol) is used for a soft segment component can be used. There are various grades of polyester-based elastomers, in accordance with a difference in the type, the ratio, and the molecular weight of the hard segment and the soft segment.

The polyamide-based elastomer is broadly divided into two types of a polyether block amide-type elastomer and a polyether ester block amide-type elastomer, in which polyamide is used for a hard segment, and polyether or polyester is used for a soft segment. Examples of the polyamide include polyamide-6, polyamide-11, and polyamide-12. Examples of the polyether include polyoxyethylene glycol, polyoxypropylene glycol, and polytetramethylene glycol.

As the acrylic elastomer, a compound containing a constitutional unit based on (meth)acrylic acid ester as a main component can be used. Examples of the (meth)acrylic acid ester include methyl (meth)acrylate, ethyl (meth)acrylate, butyl (meth)acrylate, methoxyethyl (meth)acrylate, and ethoxyethyl (meth)acrylate. The acrylic elastomer may be a compound in which (meth)acrylic acid ester and acrylonitrile are copolymerized, or may be a compound in which a monomer having a functional group to be a cross-linking point is further copolymerized. Examples of the monomer having a functional group include glycidyl methacrylate and allyl glycidyl ether.

Examples of the acrylic elastomer include an acrylonitrile-butyl acrylate copolymer, an acrylonitrile-butyl acrylate-ethyl acrylate copolymer, a methyl methacrylate-butyl acrylate-methacrylic acid copolymer, and an acrylonitrile-butyl acrylate-glycidyl methacrylate copolymer. As the acrylic elastomer, the acrylonitrile-butyl acrylate-glycidyl methacrylate copolymer or the methyl methacrylate-butyl acrylate-methacrylic acid copolymer is preferable, and the methyl methacrylate-butyl acrylate-methacrylic acid copolymer is more preferable.

The silicone-based elastomer is a compound containing organopolysiloxane as a main component. Examples of the organopolysiloxane include polydimethyl siloxane, polymethyl phenyl siloxane, and polydiphenyl siloxane. The silicone-based elastomer may be a compound in which a part of organopolysiloxane is modified with a vinyl group, an alkoxy group, or the like.

The component (I), from the viewpoint of improving the adhesiveness of the cured film, may include a carboxylic acid-modified butadiene-acrylonitrile copolymer or a polyester-based elastomer having a hydroxyl group.

The content of the component (I) may be 2 to 50 parts by mass, 4 to 45 parts by mass, 6 to 40 parts by mass, or 10 to 35 parts by mass, with respect to 100 parts by mass of the component (A). In a case where the content of the component (I) is in the range described above, the elastic modulus of the cured film in a high temperature range decreases, and the unexposed portion is more easily eluted with the developer.

### (Other Components)

The photosensitive resin composition according to this embodiment, as necessary, may further contain various additives. Examples of the additive include a thickener such as bentone and montmorillonite; silicone-based, fluorine-based, and vinyl resin-based antifoaming agents; a silane coupling agent; and a flame retarder such as a brominated epoxy compound, an acid-modified brominated epoxy compound, an antimony compound, a phosphate compound, aromatic condensed phosphoric acid ester, and halogen-containing condensed phosphoric acid ester.

### (Solvent)

By containing a solvent for dissolving and dispersing each component, the photosensitive resin composition according to this embodiment can be easily applied onto a substrate to form a coated film with an even thickness.

Examples of the solvent include ketone such as methyl ethyl ketone and cyclohexanone; aromatic hydrocarbon such as toluene, xylene, and tetramethyl benzene; glycol ether such as methyl cellosolve, butyl cellosolve, methyl carbitol, butyl carbitol, propylene glycol monomethyl ether, dipropylene glycol monoethyl ether, dipropylene glycol diethyl ether, and triethylene glycol monoethyl ether; ester such as ethyl acetate, butyl acetate, butyl cellosolve acetate, and carbitol acetate; aliphatic hydrocarbon such as octane and decane; and a petroleum-based solvent such as petroleum ether, petroleum naphtha, hydrogenated petroleum naphtha, and solvent naphtha. Only one type of the solvent may be used alone, or two or more types thereof may be used in combination.

The blending amount of the solvent is not particularly limited, and a ratio of the solvent in the photosensitive resin composition may be 10 to 60% by mass, 20 to 50% by mass, or 25 to 40% by mass.

The photosensitive resin composition of this embodiment can be prepared by homogeneously mixing each component described above with a roll mill, a bead mill, or the like.

### [Photosensitive Element]

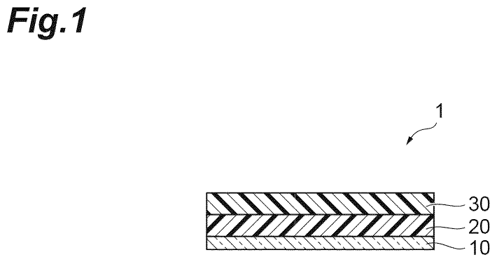

A photosensitive element according to this embodiment includes a support film, and a photosensitive layer containing the photosensitive resin composition described above. FIG. 1 is a cross-sectional view schematically illustrating the photosensitive element according to this embodiment. As illustrated in FIG. 1, a photosensitive element 1 includes a support film 10, and a photosensitive layer 20 formed on the support film 10.

The photosensitive element 1 can be produced by applying the photosensitive resin composition according to this embodiment onto the support film 10 with a known method such as reverse roll coating, gravure roll coating, comma coating, and curtain coating, and then, drying the coated film to form the photosensitive layer 20.

Examples of the support film include a polyester film such as polyethylene terephthalate and polybutylene terephthalate, and a polyolefin film such as polypropylene and polyethylene. The thickness of the support film, for example, may be 5 to 100 μm. The thickness of the photosensitive layer, for example, may be 5 to 50 μm, 5 to 40 μm, or 10 to 30 μm. The surface roughness of the support film is not particularly limited, and arithmetic average roughness (Ra) may be 1000 nm or less, 500 nm or less, or 250 nm or less.

The coated film can be dried by using hot-air drying, and drying with a far infrared ray or a near infrared ray. A drying temperature may be 60 to 120° C., 70 to 110° C., or 80 to 100° C. A drying time may be 1 to 60 minutes, 2 to 30 minutes, or 5 to 20 minutes.

A protective film 30 covering the photosensitive layer 20 may be further provided on the photosensitive layer 20. In the photosensitive element 1, the protective film 30 can also be stacked on the surface of the photosensitive layer 20 on a side opposite to the surface in contact with the support film 10. As the protective film 30, for example, a polymer film such as polyethylene and polypropylene may be used.

### [Printed Circuit Board]

A printed circuit board according to this embodiment includes a permanent resist including a cured product of the photosensitive resin composition according to this embodiment.

A method for producing a printed circuit board according to this embodiment includes a step of forming a photosensitive layer on a substrate by using the photosensitive resin composition or the photosensitive element described above, a step of exposing and developing the photosensitive layer to form a resist pattern, and a step of curing the resist pattern to form a permanent resist. Hereinafter, an example of each step will be described.

First, the substrate such as a copper clad laminate is prepared, and the photosensitive layer is formed on the substrate. The photosensitive layer may be formed by applying the photosensitive resin composition onto the substrate and drying the photosensitive resin composition. Examples of a method for applying the photosensitive resin composition include a screen printing method, a spray method, a roll coating method, a curtain coating method, and an electrostatic coating method. A drying temperature may be 60 to 120° C., 70 to 110° C., or 80 to 100° C. A drying time may be 1 to 7 minutes, 1 to 6 minutes, or 2 to 5 minutes.

The photosensitive layer may be formed by peeling the protective film from the photosensitive element, and laminating the photosensitive layer on the substrate. Examples of a method for laminating the photosensitive layer include a thermal laminating method using a laminator.

Next, the photosensitive layer is brought into contact with a negative film directly or through a support film, and irradiated with an active ray to be exposed. Examples of the active ray include an electron beam, an ultraviolet ray, and an X-ray, and the ultraviolet ray is preferable. An exposure amount may be 10 to 2000 mJ/cm², 100 to 1500 mJ/cm², or 300 to 1000 mJ/cm².

A light source of the active ray is not particularly limited insofar as the light source is a known light source that is commonly used, and for example, a light source for effectively emitting an ultraviolet ray, such as a carbon arc lamp, a mercury vapor arc lamp, a super high-pressure mercury lamp, a high-pressure mercury lamp, a xenon lamp, gas laser such as argon laser, solid-state laser such as YAG laser, semiconductor laser such as gallium nitride-based blue-violet laser, can be used. Among them, from the viewpoint of improving the resolution and an alignment property in a balanced way, a light source capable of emitting i-line monochromatic light with an exposure wavelength of 365 nm, a light source capable of emitting h-line monochromatic light with an exposure wavelength of 405 nm, or a light source capable of emitting an active ray with the exposure wavelength of an ih-mixed line may be used, and it is preferable to use the light source capable of emitting the i-line monochromatic light with an exposure wavelength of 365 nm or the h-line monochromatic light with an exposure wavelength of 405 nm. Examples of the light source capable of emitting the i-line monochromatic light with an exposure wavelength of 365 nm include a super high-pressure mercury lamp. Examples of the light source capable of emitting the h-line monochromatic light with an exposure wavelength of 405 nm include a blue-violet laser diode with a wavelength of 405 nm. Since the photosensitive layer is formed by using the photosensitive resin composition according to this embodiment, it is possible to form the via opening portion with an excellent shape at any of the exposure wavelengths described above.

After exposure, the unexposed portion is removed with the developer to form the resist pattern. Examples of a developing method include a dipping method and a spray method. As the developer, for example, an alkaline aqueous solution such as potassium hydroxide, sodium hydroxide, sodium carbonate, potassium carbonate, and tetramethyl ammonium hydroxide can be used.

By performing at least one treatment of postexposure and postheating on the resist pattern, it is possible to form a pattern cured film (the permanent resist). The exposure amount of the postexposure may be 100 to 5000 mJ/cm², 500 to 2000 mJ/cm², or 700 to 1500 J/cm². The heating temperature of the postheating may be 100 to 200° C., 120 to 180° C., or 135 to 165° C. The heating time of the postheating may be 5 minutes to 12 hours, 10 minutes to 6 hours, or 30 minutes to 2 hours.

A permanent resist according to this embodiment can be used as an interlayer dielectric layer or a surface protective layer of a semiconductor element. It is possible to produce the semiconductor element including the interlayer dielectric layer or the surface protective layer formed from the cured film of the photosensitive resin composition described above, and an electronic device including the semiconductor element. The semiconductor element, for example, may be a memory, a package, or the like, which has a multilayer wiring structure, a redistribution structure, and the like. Examples of the electronic device include a mobile phone, a smart phone, a tablet terminal, a personal computer, and a hard disk suspension. By including the pattern cured film formed by the photosensitive resin composition according to this embodiment, it is possible to provide the semiconductor element and the electronic device excellent in reliability.

### EXAMPLES

Hereinafter, the present disclosure will be described in more detail by Examples, but the present disclosure is not limited to such Examples.

### Synthesis of Acid-Modified Vinyl Group-Containing Resin (A)

### Synthesis Example 1

350 parts by mass of a dicyclopentadiene-type epoxy resin (manufactured by Nippon Kayaku Co., Ltd., Product Name “XD-1000”, Epoxy Equivalent: 252 g/eq, Softening Point: 74.2° C., Number of Ring-Forming Carbon Atoms of Alicyclic Skeleton: 10), 70 parts by mass of an acrylic acid, 0.5 parts by mass of methyl hydroquinone, and 120 parts by mass of carbitol acetate were prepared, and stirred by heating to 90° C. to cause a reaction such that the mixture was dissolved. Next, the obtained solution was cooled to 60° C., 2 parts by mass of triphenyl phosphine was added thereto, and the solution was heated to 100° C. to cause a reaction until the acid value of the solution was 1 mgKOH/g. 98 parts by mass of a tetrahydrophthalic anhydride and 85 parts by mass of carbitol acetate were added to the solution after the reaction, and heated to 80° C. to cause a reaction for 6 hours. After that, the solution was cooled to a room temperature to obtain a solution of acid-modified dicyclopentadiene-type epoxy acrylate (A-1) with a solid content concentration of 73% by mass.

### Synthesis Example 2

350 parts by mass of a dicyclopentadiene-type epoxy resin (manufactured by DIC Corporation, Product Name “EPICLON (Registered Trademark) HP-7200”, Epoxy Equivalent: 254 to 264 g/eq, Softening Point: 56 to 66° C., Number of Ring-Forming Carbon Atoms of Alicyclic Skeleton: 10), 70 parts by mass of an acrylic acid, 0.5 parts by mass of methyl hydroquinone, and 120 parts by mass of carbitol acetate were prepared, and stirred by heating to 90° C. to cause a reaction such that the mixture was dissolved. Next, the obtained solution was cooled to 60° C., 2 parts by mass of triphenyl phosphine was added thereto, and the solution was heated to 100° C. to cause a reaction until the acid value of the solution was 1 mgKOH/g. 98 parts by mass of a tetrahydrophthalic anhydride and 85 parts by mass of carbitol acetate were added to the solution after the reaction, and heated to 80° C. to cause a reaction for 6 hours. After that, the solution was heated to a room temperature to obtain a solution of acid-modified dicyclopentadiene-type epoxy acrylate (A-2) with a solid content concentration of 74% by mass.

### Synthesis Example 3

350 parts by mass of a bisphenol F novolac-type epoxy resin (manufactured by DIC Corporation, Product Name “EXA-7376”), 70 parts by mass of an acrylic acid, 0.5 parts by mass of methyl hydroquinone, and 120 parts by mass of carbitol acetate were prepared, and stirred by heating to 90° C. to cause a reaction such that the mixture was dissolved. Next, the obtained solution was cooled to 60° C., 2 parts by mass of triphenyl phosphine was added thereto, and the solution was heated to 100° C. to cause a reaction until the acid value of the solution was 1 mgKOH/g. 98 parts by mass of a tetrahydrophthalic anhydride and 85 parts by mass of carbitol acetate were added to the solution after the reaction, and heated to 80° C. to cause a reaction for 6 hours. After that, the solution was cooled to a room temperature to obtain a solution of acid-modified bisphenol F-type epoxy acrylate (A-3) with a solid content concentration of 73% by mass.

### <Preparation of Components (B) to (H)>

As components (B) to (H), the following materials were prepared.

### Photopolymerization Initiator (B)

Alkyl Phenone-Based Photopolymerization Initiator (B1)
B1-1:2-benzyl-2-dimethyl amino-1-(4-morpholinophenyl)-butanone-1 (manufactured by IGM Resins B.V., Product Name “Omnirad 369”)
B1-2: 2-hydroxy-1-[4-(2-hydroxyethoxy)phenyl]-2-methyl-1-propanone (manufactured by IGM Resins B.V., Product Name “Omnirad 2959”)
B1-3: 2-methyl-1-[4-(methyl thio)phenyl]-2-morpholino-1-propanone (manufactured by IGM Resins B.V., Product Name “Omnirad 907”)

### Oxime Ester-Based Photopolymerization Initiator (B2)

B2-1: ethanone, 1-[9-ethyl-6-(2-methyl benzoyl)-9H-carbazol-3-yl]-, 1-(O-acetyl oxime) (manufactured by BASF, Product Name “Irgacure OXE02”)
B2-2: 1-[4-(phenyl thio)phenyl] octane-1,2-dione=2-(O-benzoyl oxime) (manufactured by BASF, Product Name “Irgacure OXE01”)

### Benzophenone-Based Photopolymerization Initiator (B3)

B3-1: 4,4′-bis(diethyl amino)benzophenone (manufactured by Tokyo Aniline Dyestuff Mfg. Co., Ltd., Product Name “EAB”)

### Other Photopolymerization Initiators (B4)

B4-1: 2,4-diethyl thioxanthone (manufactured by Nippon Kayaku Co., Ltd., Product Name “DETX-S”)

### Photopolymerizable Compound (C)

C-1: dipentaerythritol hexaacrylate (manufactured by Nippon Kayaku Co., Ltd., Product Name “DPHA”)

### Polymerization Inhibitor (D)

D-1: 4,4′-butylidene-bis(6-tert-butyl-m-cresol) (manufactured by Kawaguchi Chemical Industry Co., LTD., Product Name “ANTAGE W-300”)

### Pigment (F)

F-1: a phthalocyanine-based pigment (manufactured by SANYO COLOR WORKS, Ltd.)

### Inorganic Filler (G)

G-1: silica particles (manufactured by Denka Company Limited, Product Name “SFP-20M”, Average Particle Size: 0.3 μm)

### Thermosetting Resin (H)

H-1: a biphenyl-type epoxy resin (manufactured by Mitsubishi Chemical Corporation, Product Name “YX4000”)

### Examples 1 to 19 and Comparative Examples 1 to 6

### <Preparation of Photosensitive Resin Composition>

Each component was blended in accordance with a blending composition shown in Table 1 to Table 3 (the unit of numerical values in the tables is parts by mass, and is in terms of a solid content in the case of a solution), and kneaded with a three-roll mill. After that, methyl ethyl ketone was added such that a solid content concentration was 60% by mass, and a photosensitive resin composition was obtained.

### <Production of Photosensitive Element>

As a support film, a polyethylene terephthalate film (manufactured by TEIJIN LIMITED, Product Name “G2-16”) with a thickness of 16 μm was prepared. The photosensitive resin composition was applied onto the support film such that a thickness after drying was 20 μm, and dried at 75° C. for 30 minutes by using a hot-air convection dryer to form a photosensitive layer. Subsequently, a polyethylene film (manufactured by TAMAPOLY CO., LTD., Product Name “NF-15”) was stuck onto the surface of the photosensitive layer on a side opposite to the surface in contact with the support film as a protective film to obtain a photosensitive element.

[1. Evaluation of Resolution of Via (i-Line)]

### (1-1) Production of Stacked Body for Evaluation

In a substrate for a printed circuit board (manufactured by Resonac Corporation, Product Name “MCL-E-679”) in which a copper foil with a thickness of 12 μm was stacked on a glass epoxy base material, the copper foil surface was treated with a roughening treatment liquid (manufactured by MEC Co., Ltd., Product Name “CZ-8100”), and then, washed with water and dried to obtain a roughened substrate for a printed circuit board. Next, the protective film was peeled and removed from the photosensitive element produced in each of Examples and Comparative Examples, and the exposed photosensitive layer was placed to be in contact with the copper foil of the roughened substrate for a printed circuit board, and then, a laminating treatment was performed by using a press-type vacuum laminator (manufactured by MEIKI CO., LTD., Product Name “MVLP-500”). Note that as a laminating condition, a press hot plate temperature was 70° C., a vacuumizing time was 20 seconds, a laminating press time was 30 seconds, an atmospheric pressure was 4 kPa or less, and a crimping pressure was 0.4 MPa. After the laminating treatment, the substrate was left to stand at a room temperature for 1 hour or longer to obtain a stacked body for evaluation in which the photosensitive layer and the support film were stacked in this order on the copper foil surface of the substrate for a printed circuit board.

### (1-2) Measurement of Sensitivity of Photosensitive Layer

The support film of the stacked body for evaluation obtained in (1-1) described above was peeled and removed, and then, a 41-stage step tablet (manufactured by Resonac Corporation) was disposed to perform exposure by using an i-line exposure machine (manufactured by Ushio Inc., Product Name “UX-2240SM-XJ-01”). As an exposure pattern, a negative mask having a via pattern with an opening diameter of 50 μmϕ was used. After exposure, the stacked body was left to stand at a room temperature for 30 minutes, and then, the photosensitive resin composition in an unexposed portion was spray-developed for 60 seconds by using 1% by mass of a sodium carbonate aqueous solution at 30° C. The test described above was performed while changing an exposure energy amount by 25 mJ/cm² in a range of 100 to 1000 mJ/cm², and an exposure energy amount in which the number of remaining steps of the 41-stage step tablet after developing was 10.0 was set as the sensitivity (Unit: mJ/cm²) of the photosensitive layer. By using a pattern exposed at such a sensitivity, the resolution of a via provided in the photosensitive layer was evaluated by the following method. In addition, the sensitivity was evaluated in accordance with the following criteria.

### <Evaluation Criteria>

A: the sensitivity is 150 mJ/cm² or less.
B: the sensitivity is greater than 150 mJ/cm² and 200 mJ/cm² or less.
C: the sensitivity is greater than 200 mJ/cm² and 300 mJ/cm² or less.
D: the sensitivity is greater than 300 mJ/cm².

### (1-3) Evaluation of Resolution of Via

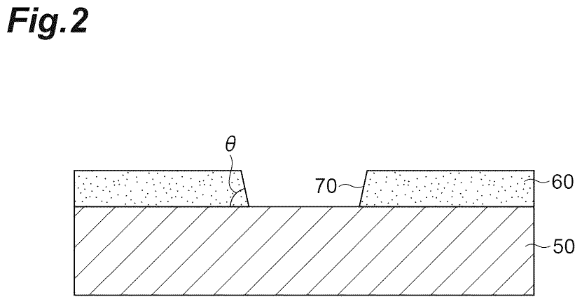

In the evaluation of the resolution of the via, the photosensitive layer was exposed at the sensitivity of the photosensitive layer measured in (1-2) described above, that is, the exposure energy amount in which the number of remaining steps was 10.0, and then, spray-developed, and then, a via pattern of the obtained cured film (a permanent resist) was observed with an optical microscope, and evaluated in accordance with the following criteria. Here, a state where the via is “opened” indicates a state where the copper foil of the substrate for a printed circuit board is visible when a via opening portion is observed with an optical microscope from directly above. In addition, a “taper angle”, as illustrated in FIG. 2, indicates an angle θ between a permanent resist 60 and a substrate 50 for a printed circuit board when the cross section of a via opening portion 70 in which the permanent resist 60 is formed on the substrate 50 for a printed circuit board is observed with an optical microscope. It can be said that as the taper angle θ becomes closer to 90 degrees, the shape of the via opening portion becomes more excellent. In a case where an evaluation result is evaluation A or evaluation B, it was determined that it was possible to form the via opening portion with an excellent shape. Note that in a case where the sensitivity is evaluation D, the resolution of the via was not evaluated.

### <Evaluation Criteria>

A: the via is opened, and the taper angle is greater than 80 degrees and 90 degrees or less.
B: the via is opened, and the taper angle is greater than 70 degrees and 80 degrees or less.
C: the via is opened, and the taper angle is greater than 60 degrees and 70 degrees or less.
D: the via is opened, and the taper angle is 60 degrees or less.
E: the via is not opened.

### [2. Evaluation of Resolution of Via (Mixed Line)]

### (2-1) Production of Stacked Body for Evaluation

As with (1-1) described above, a stacked body for evaluation was produced.

### (2-2) Measurement of Sensitivity of Photosensitive Layer

The support film of the stacked body for evaluation obtained in (2-1) described above was peeled and removed, and then a 41-stage step tablet (manufactured by Resonac Corporation) was disposed to perform exposure by using a direct imaging exposure machine (manufactured by ORC MANUFACTURING CO., LTD., Product Name “EDi-5308”, a 355-420 filter, a mixed line of an i-line and an h-line) using a super high-pressure mercury lamp as a light source. As an exposure pattern, a pattern in which dots were arranged into the shape of a grid (Diameter of Dot: Center-to-Center Distance of Dots=1:2) was used. The diameter (ϕ) of the dot was 50 μm. After exposure, the stacked body was left to stand at a room temperature for 30 minutes, and then, the photosensitive resin composition in an unexposed portion was spray-developed for 60 seconds by using 1% by mass of a sodium carbonate aqueous solution at 30° C. The test described above was performed while changing an exposure energy amount by 10 mJ/cm² in a range of 50 to 150 mJ/cm², and an exposure energy amount in which the number of remaining steps of the 41-stage step tablet after developing was 10.0 was set as the sensitivity (Unit: mJ/cm²) of the photosensitive layer. By using a pattern exposed at such a sensitivity, the resolution of a via provided in the photosensitive layer was evaluated by the following method. In addition, the sensitivity was evaluated in accordance with the following criteria.

### <Evaluation Criteria>

A: the sensitivity is 80 mJ/cm² or less.
B: the sensitivity is greater than 80 mJ/cm² and 100 mJ/cm² or less.
C: the sensitivity is greater than 100 mJ/cm² and 150 mJ/cm² or less.
D: the sensitivity is greater than 150 mJ/cm².

### (2-3) Evaluation of Resolution of Via

As with (1-3) described above, the resolution of the via was evaluated. Evaluation criteria are as follows. In a case where an evaluation result is evaluation A or evaluation B, it was determined that it was possible to form the via opening portion with an excellent shape. Note that in a case where the sensitivity is evaluation D, the resolution of the via was not evaluated.

### <Evaluation Criteria>

A: the via is opened, and the taper angle is greater than 80 degrees and 90 degrees or less.
B: the via is opened, and the taper angle is greater than 70 degrees and 80 degrees or less.
C: the via is opened, and the taper angle is greater than 60 degrees and 70 degrees or less.
D: the via is opened, and the taper angle is 60 degrees or less.
E: the via is not opened.

TABLE 1

| | | | Example | | | | | | | |
|---|---|---|---|---|---|---|---|---|---|---|
| | | | 1 | 2 | 3 | 4 | 5 | 6 | 7 | 8 |
| Component (A) | A-1 | Synthesis | 36 | — | — | 36 | 36 | 36 | 36 | 36 |
| | | Example 1 | | | | | | | | |
| | A-2 | Synthesis | — | 36 | — | — | — | — | — | — |
| | | Example 2 | | | | | | | | |
| | A-3 | Synthesis | — | — | 36 | — | — | — | — | — |
| | | Example 3 | | | | | | | | |
| Component (B) | B1-1 | Omnirad 369 | 1 | 1 | 1 | — | 1 | 0.1 | 0.5 | 1 |
| | B1-2 | Omnirad 2959 | — | — | — | 1 | — | — | — | — |
| | B2-1 | Irgacure OXE02 | 0.05 | 0.05 | 0.05 | 0.05 | — | 0.5 | 0.025 | 0.05 |
| | B2-2 | Irgacure OXE01 | — | — | — | — | 0.05 | — | — | — |
| | B3-1 | EAB | 0.05 | 0.05 | 0.05 | 0.05 | 0.05 | 0.1 | 0.06 | 0.05 |
| | B4-1 | DETX-S | 0.05 | 0.05 | 0.05 | 0.05 | 0.05 | 0.1 | 0.05 | — |
| Component (C) | C-1 | DPHA | 4.5 | 4.5 | 4.5 | 4.5 | 4.5 | 4.5 | 4.5 | 4.5 |
| Component (D) | D-1 | ANTAGE W-300 | 0.05 | 0.05 | 0.05 | 0.05 | 0.05 | 0.05 | 0.04 | 0.05 |
| Component (F) | F-1 | Phthalocyanine- | 0.24 | 0.24 | 0.24 | 0.24 | 0.24 | 0.24 | 0.24 | 0.24 |
| | | based pigment | | | | | | | | |
| Component (G) | G-1 | SFP-20M | 39 | 39 | 39 | 39 | 39 | 39 | 39 | 39 |
| Component (H) | H-1 | YX4000X | 10 | 10 | 10 | 10 | 10 | 10 | 10 | 10 |

| | | | | | | | | | |
|---|---|---|---|---|---|---|---|---|---|
| i-Line | Sensitivity | A | A | A | A | A | C | C | B |
| | Shape of via opening | A | A | A | A | A | A | A | A |
| | portion | | | | | | | | |
| Mixed line | Sensitivity | A | A | A | A | A | C | C | B |
| | Shape of via opening | A | A | A | A | A | A | B | B |
| | portion | | | | | | | | |

TABLE 2

| | | | Example | | Comparative Example | | | | | |
|---|---|---|---|---|---|---|---|---|---|---|
| | | | 9 | 10 | 1 | 2 | 3 | 4 | 5 | 6 |
| Component (A) | A-1 | Synthesis | 36 | 36 | 36 | 36 | 36 | 36 | 36 | 36 |
| | | Example 1 | | | | | | | | |
| | A-2 | Synthesis | — | — | — | — | — | — | — | — |
| | | Example 2 | | | | | | | | |
| | A-3 | Synthesis | — | — | — | — | — | — | — | — |
| | | Example 3 | | | | | | | | |
| Component (B) | B1-1 | Omnirad 369 | 1 | 1 | — | 1 | 1 | 0.1 | — | 1 |
| | B1-2 | Omnirad 2959 | — | — | — | — | — | — | — | — |
| | B2-1 | Irgacure OXE02 | 0.05 | 0.025 | 0.05 | — | 0.05 | 0.05 | 0.25 | 0.05 |
| | B2-2 | Irgacure OXE01 | — | — | — | — | — | — | — | — |
| | B3-1 | EAB | 0.025 | 0.05 | 0.05 | 0.05 | — | — | 0.25 | 0.05 |
| | B4-1 | DETX-S | 0.05 | 0.05 | 0.05 | 0.05 | 0.05 | 0.05 | 0.25 | 0.05 |
| Component (C) | C-1 | DPHA | 4.5 | 4.5 | 4.5 | 4.5 | 4.5 | 4.5 | 4.5 | 4.5 |
| Component (D) | D-1 | ANTAGE W-300 | 0.05 | 0.05 | 0.05 | 0.05 | 0.05 | 0.05 | 0.25 | — |
| Component (F) | F-1 | Phthalocyanine- | 0.24 | 0.24 | 0.24 | 0.24 | 0.24 | 0.24 | 0.24 | 0.24 |
| | | based pigment | | | | | | | | |
| Component (G) | G-1 | SFP-20M | 39 | 39 | 39 | 39 | 39 | 39 | 39 | 39 |
| Component (H) | H-1 | YX4000X | 10 | 10 | 10 | 10 | 10 | 10 | 10 | 10 |

| | | | | | | | | | |
|---|---|---|---|---|---|---|---|---|---|
| i-Line | Sensitivity | B | B | D | C | C | A | D | A |
| | Shape of via opening | B | B | — | C | C | E | — | C |
| | portion | | | | | | | | |
| Mixed line | Sensitivity | C | C | D | D | D | A | D | A |
| | Shape of via opening | B | B | — | — | — | E | — | C |
| | portion | | | | | | | | |

TABLE 3

| | | | Example | | | | | | | | |
|---|---|---|---|---|---|---|---|---|---|---|---|
| | | | 11 | 12 | 13 | 14 | 15 | 16 | 17 | 18 | 19 |
| Component (A) | A-1 | Synthesis Example 1 | 36 | 36 | 36 | 36 | 36 | 36 | 36 | 36 | 36 |
| | A-2 | Synthesis Example 2 | — | — | — | — | — | — | — | — | — |
| | A-3 | Synthesis Example 3 | — | — | — | — | — | — | — | — | — |
| Component (B) | B1-1 | Omnirad 369 | — | 1 | 1 | — | 1 | 1 | 1 | 1 | 1 |
| | B1-2 | Omnirad 2959 | — | — | — | — | — | — | — | — | — |
| | B1-3 | Omnirad 907 | 1 | — | — | 1 | — | — | — | — | — |
| | B2-1 | Irgacure OXE02 | 0.05 | 0.05 | 0.05 | 0.05 | 0.05 | 0.05 | 0.05 | 0.05 | 0.05 |
| | B2-2 | Irgacure OXE01 | — | — | — | — | — | — | — | — | — |
| | B3-1 | EAB | 0.05 | 0.05 | 0.05 | 0.05 | 0.05 | 0.05 | 0.05 | 0.05 | 0.05 |
| | B4-1 | DETX-S | 0.05 | 0.1 | 0.01 | — | 0.05 | 0.05 | 0.05 | 0.05 | 0.05 |
| Component (C) | C-1 | DPHA | 4.5 | 4.5 | 4.5 | 4.5 | 4.5 | 4.5 | 4.5 | 4.5 | 4.5 |
| Component (D) | D-1 | ANTAGE W-300 | 0.05 | 0.05 | 0.05 | 0.05 | 0.1 | 0.01 | 0.05 | 0.05 | 0.05 |
| Component (F) | F-1 | Phthalocyanine- | 0.24 | 0.24 | 0.24 | 0.24 | 0.24 | 0.24 | 0.24 | 0.24 | 0.24 |
| | | based pigment | | | | | | | | | |
| Component (G) | G-1 | SFP-20M | 39 | 39 | 39 | 39 | 39 | 39 | 45 | 30 | 20 |
| Component (H) | H-1 | YX4000X | 10 | 10 | 10 | 10 | 10 | 10 | 10 | 10 | 10 |

| | | | | | | | | | | |
|---|---|---|---|---|---|---|---|---|---|---|
| i-Line | Sensitivity | A | A | B | B | B | A | A | A | B |
| | Shape of via opening portion | A | A | A | A | A | B | A | B | B |
| Mixed line | Sensitivity | A | A | B | B | B | A | A | B | B |
| | Shape of via opening portion | A | A | A | B | A | B | A | B | B |

### REFERENCE SIGNS LIST

1: photosensitive element, 10: support film, 20: photosensitive layer, 30: protective film, 50: substrate for printed circuit board, 60: permanent resist, 70: via opening portion.

1. A photosensitive resin composition, comprising:
an acid-modified vinyl group-containing resin (A);
a photopolymerization initiator (B);
a photopolymerizable compound (C); and
a polymerization inhibitor (D),
wherein the photopolymerization initiator (B) includes an alkyl phenone-based photopolymerization initiator (B1), an oxime ester-based photopolymerization initiator (B2), and a benzophenone-based photopolymerization initiator (B3).

2. The photosensitive resin composition according to claim 1,
wherein a content of the alkyl phenone-based photopolymerization initiator (B1) is 30% by mass or more, on the basis of a total amount of the alkyl phenone-based photopolymerization initiator (B1), the oxime ester-based photopolymerization initiator (B2), and the benzophenone-based photopolymerization initiator (B3).

3. The photosensitive resin composition according to claim 1,
wherein a content of the oxime ester-based photopolymerization initiator (B2) is 0.5 to 30% by mass, on the basis of a total amount of the alkyl phenone-based photopolymerization initiator (B1), the oxime ester-based photopolymerization initiator (B2), and the benzophenone-based photopolymerization initiator (B3).

4. The photosensitive resin composition according to claim 1,
wherein a content of the benzophenone-based photopolymerization initiator (B3) is 0.2 to 50% by mass, on the basis of a total amount of the alkyl phenone-based photopolymerization initiator (B1), the oxime ester-based photopolymerization initiator (B2), and the benzophenone-based photopolymerization initiator (B3).

5. The photosensitive resin composition according to claim 1, further comprising
a sensitizer (E).

6. The photosensitive resin composition according to claim 1, further comprising
a pigment (F).

7. The photosensitive resin composition according to claim 1, further comprising
an inorganic filler (G).

8. The photosensitive resin composition according to claim 1,
wherein the photopolymerization initiator (B) further includes a thioxanthone compound (B4).

9. The photosensitive resin composition according to claim 8,
wherein a content of the thioxanthone compound (B4) is 0.1 to 50 parts by mass, with respect to 100 parts by mass of a total amount of the alkyl phenone-based photopolymerization initiator (B1), the oxime ester-based photopolymerization initiator (B2), and the benzophenone-based photopolymerization initiator (B3).

10. A photosensitive element, comprising:
a support film; and
a photosensitive layer formed on the support film,
wherein the photosensitive layer contains the photosensitive resin composition according to claim 1.

11. A printed circuit board, comprising
a permanent resist including a cured product of the photosensitive resin composition according to claim 1.

12. A method for producing a printed circuit board, comprising:
a step of forming a photosensitive layer on a substrate by using the photosensitive resin composition according to claim 1;
a step of exposing and developing the photosensitive layer to form a resist pattern; and
a step of curing the resist pattern to form a permanent resist.

13. A method for producing a printed circuit board, comprising:
a step of forming a photosensitive layer on a substrate by using the photosensitive element according to claim 10;
a step of exposing and developing the photosensitive layer to form a resist pattern; and
a step of curing the resist pattern to form a permanent resist.
